(19) United States
(12) Patent Application Publication
(10) Pub. No.: US 2025/0063764 A1
(43) Pub. Date: Feb. 20, 2025

(54) SEMICONDUCTOR DEVICE STRUCTURE WITH CONTACT STRUCTURE AND METHOD FOR FORMING THE SAME

(71) Applicant: Taiwan Semiconductor Manufacturing Company, Ltd., Hsinchu (TW)

(72) Inventors: Ta-Chun LIN, Hsinchu (TW); Ming-Heng TSAI, Taipei City (TW)

(21) Appl. No.: 18/449,824

(22) Filed: Aug. 15, 2023

(51) Int. Cl. H01L 29/417; H01L 21/285; H01L 29/06; H01L 29/40; H01L 29/423; H01L 29/66; H01L 29/775

(52) U.S. Cl. CPC H01L 29/41733; H01L 21/28518; H01L 29/0673; H01L 29/401; H01L 29/42392; H01L 29/66439; H01L 29/775

(57) ABSTRACT

A method for forming a semiconductor device structure is provided. The method includes providing a substrate and a nanostructure stack. The method includes forming a first gate stack and a second gate stack wrapped around the nanostructure stack. The method includes forming a first source/drain structure in the nanostructure stack and between the first gate stack and the second gate stack. The method includes removing the second gate stack, the nanostructure stack and the fin under the second gate stack to form a trench passing through the nanostructure stack and the fin. The method includes forming a dielectric isolation structure in the trench. The method includes removing the first gate stack and the first nanostructure. The method includes forming a third gate stack wrapped around the second nanostructure. The method includes forming a first contact structure over the first source/drain structure.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1B are top views of various stages of a process for forming a semiconductor device structure, in accordance with some embodiments.

FIGS. 1A-1 to 1B-1 are perspective views of the semiconductor device structure of FIGS. 1A-1B, in accordance with some embodiments.

FIGS. 2A-2M are cross-sectional views of various stages of a process for forming a semiconductor device structure, in accordance with some embodiments.

FIG. 2D-1 is a top view of the semiconductor device structure of FIG. 2D, in accordance with some embodiments.

FIG. 2E-1 is a top view of the semiconductor device structure of FIG. 2E, in accordance with some embodiments.

FIG. 2F-1 is a top view of the semiconductor device structure of FIG. 2F, in accordance with some embodiments.

FIG. 2G-1 is a top view of the semiconductor device structure of FIG. 2G, in accordance with some embodiments.

FIG. 2H-1 is a top view of the semiconductor device structure of FIG. 2H, in accordance with some embodiments.

FIG. 2I-1 is a top view of the semiconductor device structure of FIG. 2I, in accordance with some embodiments.

FIG. 2J-1 is a top view of the semiconductor device structure of FIG. 2J, in accordance with some embodiments.

FIG. 2K-1 is a top view of the semiconductor device structure of FIG. 2K, in accordance with some embodiments.

FIG. 2K-2 is a cross-sectional view illustrating the semiconductor device structure along a sectional line II-II′ in FIG. 2K-1, in accordance with some embodiments.

FIG. 2L-1 is a top view of the semiconductor device structure of FIG. 2L, in accordance with some embodiments.

FIG. 2M-1 is a top view of the semiconductor device structure of FIG. 2M, in accordance with some embodiments.

FIG. 2M-2 is a top view of the semiconductor device structure of FIG. 2M, in accordance with some embodiments.

FIG. 3A is a cross-sectional view of a semiconductor device structure, in accordance with some embodiments.

FIG. 3B is a top view of the semiconductor device structure of FIG. 3A, in accordance with some embodiments.

FIG. 4A is a cross-sectional view of a semiconductor device structure, in accordance with some embodiments.

FIG. 4B is a top view of the semiconductor device structure of FIG. 4A, in accordance with some embodiments.

FIG. 5A is a cross-sectional view of a semiconductor device structure, in accordance with some embodiments.

FIG. 5B is a top view of the semiconductor device structure of FIG. 5A, in accordance with some embodiments.

FIG. 6 is a cross-sectional view of a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

The nanostructure transistor (e.g. nanosheet transistor, nanowire transistor, multi-bridge channel, nano-ribbon FET, gate all around (GAA) transistor structures) described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

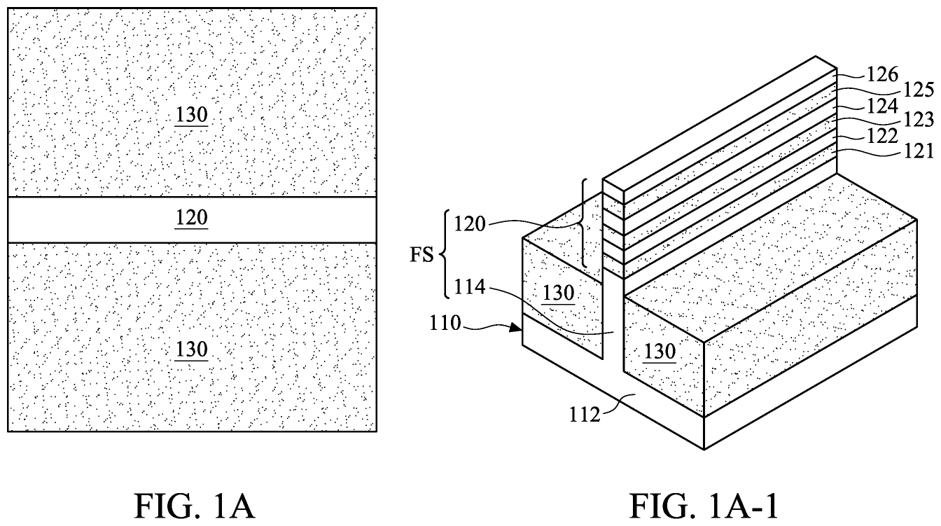

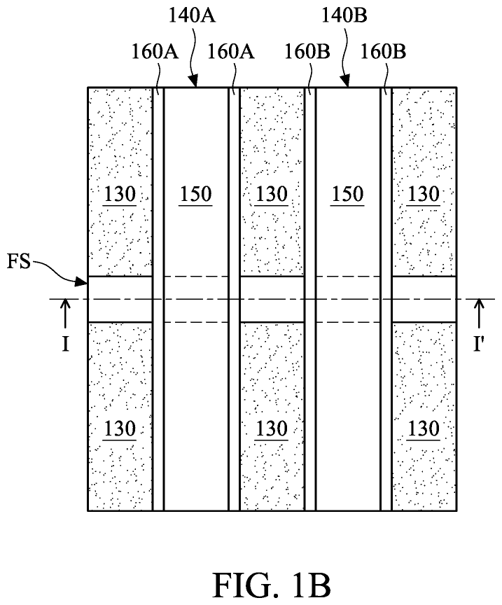

FIGS. 1A-1B are top views of various stages of a process for forming a semiconductor device structure, in accordance with some embodiments. FIGS. 1A-1 to 1B-1 are perspective views of the semiconductor device structure of FIGS. 1A-1B, in accordance with some embodiments.

As shown in FIGS. 1A and 1A-1, a substrate 110 is provided, in accordance with some embodiments. The substrate 110 has a base 112 and a fin 114 over the base 112, in accordance with some embodiments.

The substrate 110 includes, for example, a semiconductor substrate. The substrate 110 includes, for example, a semiconductor wafer (such as a silicon wafer) or a portion of a semiconductor wafer. In some embodiments, the substrate 110 is made of an elementary semiconductor material including silicon or germanium in a single crystal structure, a polycrystal structure, or an amorphous structure.

In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity.

Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIGS. 1A and 1A-1, a nanostructure stack 120 is formed over the fin 114, in accordance with some embodiments. The nanostructure stack 120 and the fin 114 together form a fin structure FS, in accordance with some embodiments.

The nanostructure stack 120 includes nanostructures 121, 122, 123, 124, 125, and 126, in accordance with some embodiments. The nanostructures 121, 122, 123, 124, 125, and 126 are sequentially stacked over the fin 114, in accordance with some embodiments. The nanostructures 121, 122, 123, 124, 125, and 126 include nanowires or nanosheets, in accordance with some embodiments.

The nanostructures 121, 123, and 125 are all made of the same first material, in accordance with some embodiments. The first material is different from the material of the substrate 110, in accordance with some embodiments. The first material includes an elementary semiconductor material including silicon or germanium in a single crystal structure, a polycrystal structure, or an amorphous structure, in accordance with some embodiments.

The first material includes a compound semiconductor, such as silicon carbide, gallium arsenide, gallium phosphide, indium phosphide, indium arsenide, an alloy semiconductor, such as SiGe or GaAsP, or a combination thereof, in accordance with some embodiments.

The nanostructures 122, 124, and 126 are all made of the same second material, in accordance with some embodiments. The second material is different from the first material, in accordance with some embodiments. The second material is the same as the material of the substrate 110, in accordance with some embodiments. The second material includes an elementary semiconductor material including silicon or germanium in a single crystal structure, a polycrystal structure, or an amorphous structure, in accordance with some embodiments.

The second material includes a compound semiconductor, an alloy semiconductor, or a combination thereof, in accordance with some embodiments. The compound semiconductor includes silicon carbide, gallium arsenide, gallium phosphide, indium phosphide, indium arsenide, a combination thereof, or another suitable compound semiconductor material, in accordance with some embodiments. The alloy semiconductor includes SiGe, SiGeSn, SiGeC, SiSn, GaAsP, GeSn, a combination thereof, or another suitable alloy semiconductor material, in accordance with some embodiments.

As shown in FIG. 1A, an isolation layer 130 is formed over the base 112, in accordance with some embodiments. The fin 114 is partially embedded in the isolation layer 130, in accordance with some embodiments. The fin 114 is surrounded by the isolation layer 130, in accordance with some embodiments.

The isolation layer 130 is made of a dielectric material such as an oxide-containing material (e.g., silicon oxide), an oxynitride-containing material (e.g., silicon oxynitride), a low-k (low dielectric constant) material, a porous dielectric material, glass, or a combination thereof, in accordance with some embodiments. The glass includes borosilicate glass (BSG), phosphoric silicate glass (PSG), borophosphosilicate glass (BPSG), fluorinated silicate glass (FSG), or a combination thereof, in accordance with some embodiments.

The isolation layer 130 is formed using a deposition process (or a spin-on process), a chemical mechanical polishing process, and an etching back process, in accordance with some embodiments. The deposition process includes a chemical vapor deposition (CVD) process, a high density plasma chemical vapor deposition (HDPCVD) process, a flowable chemical vapor deposition (FCVD) process, a sputtering process, or a combination thereof, in accordance with some embodiments.

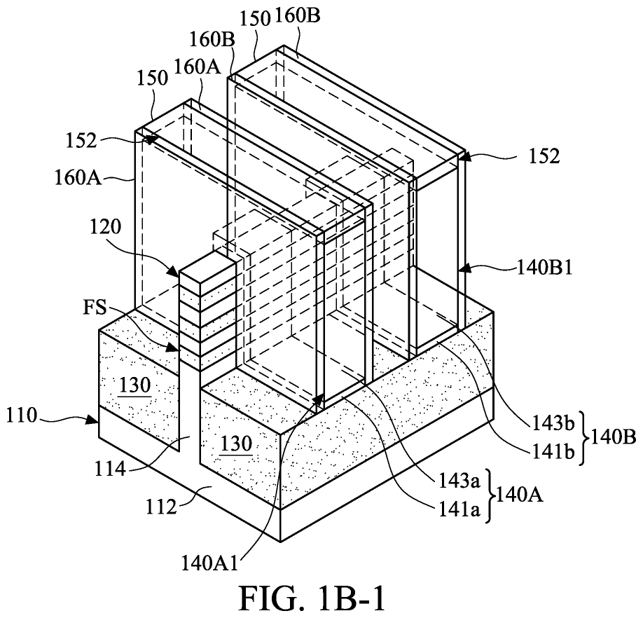

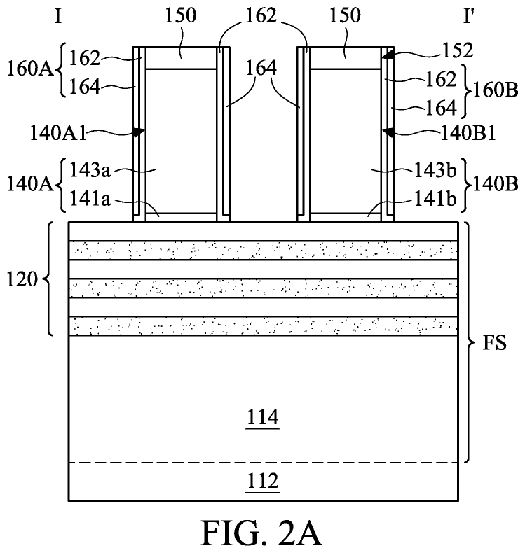

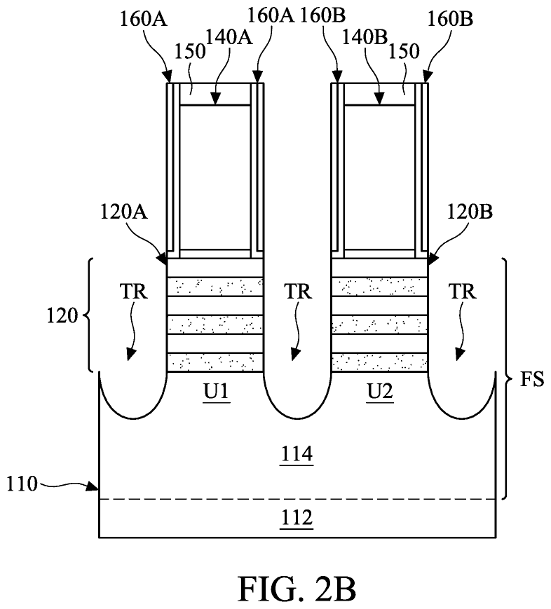

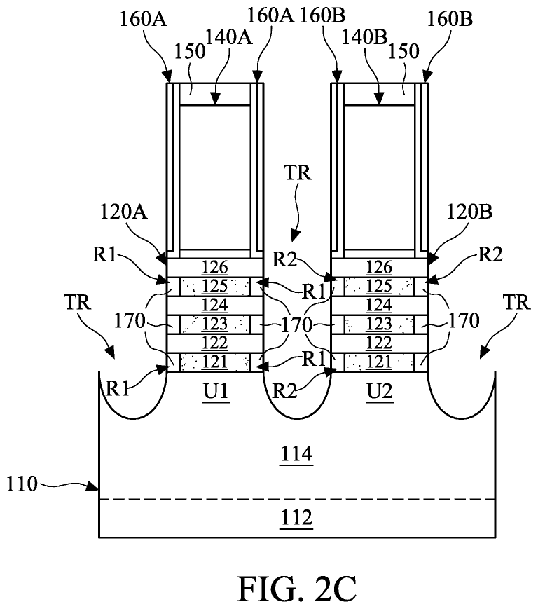

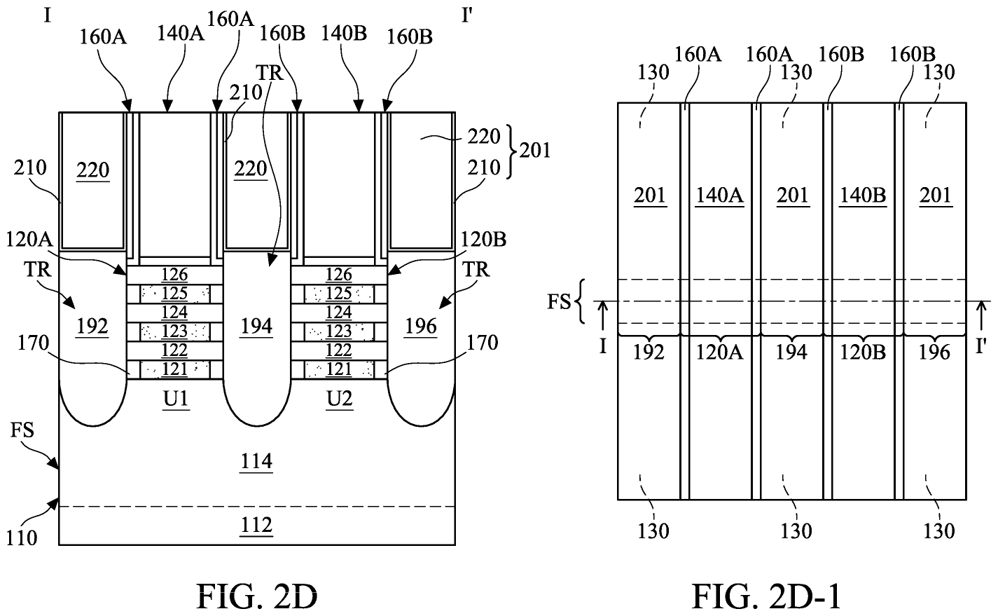

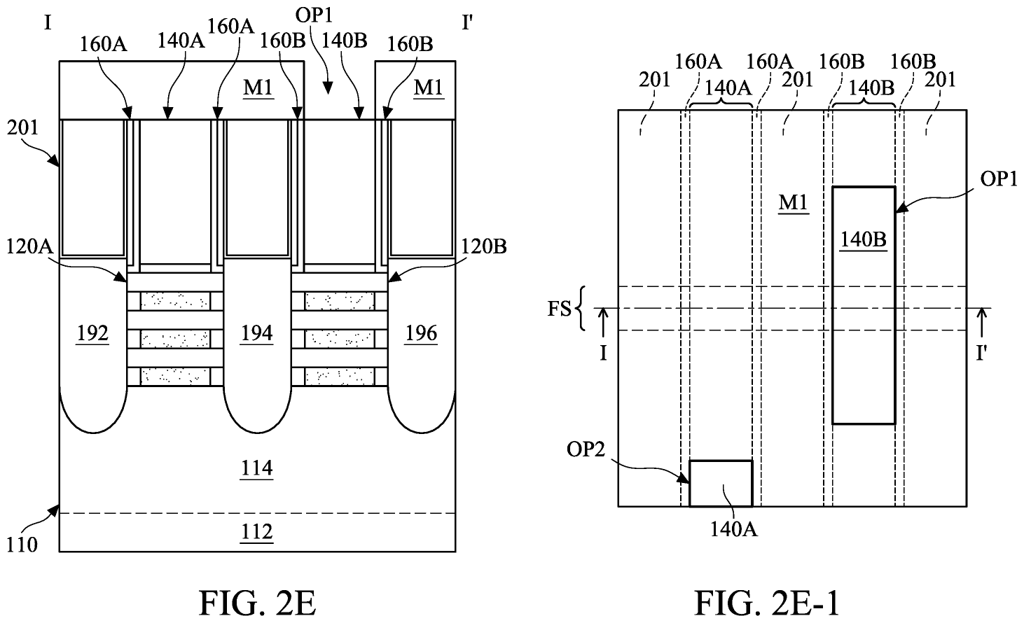

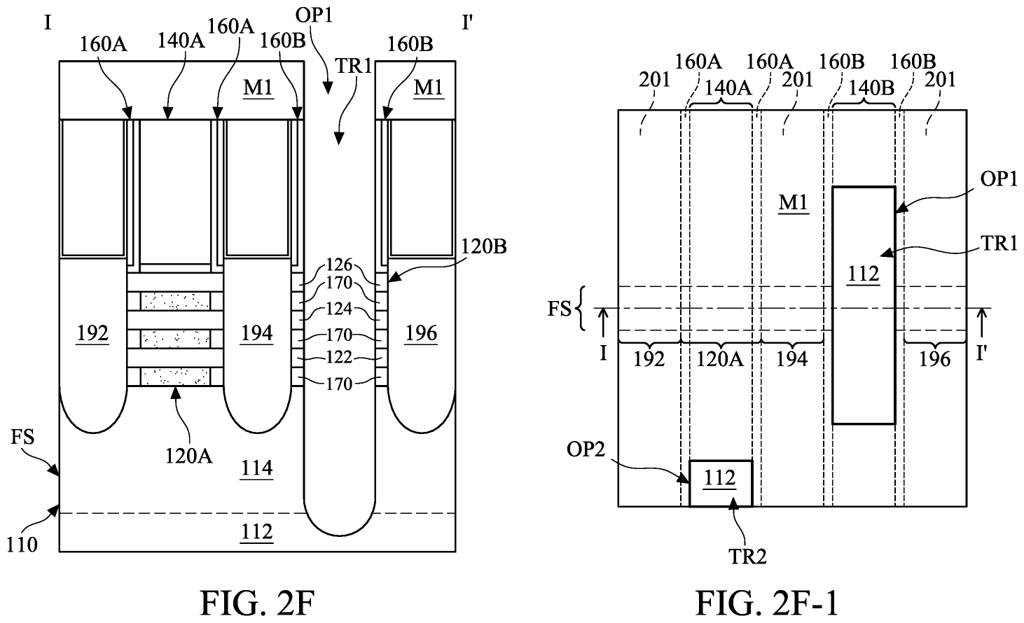

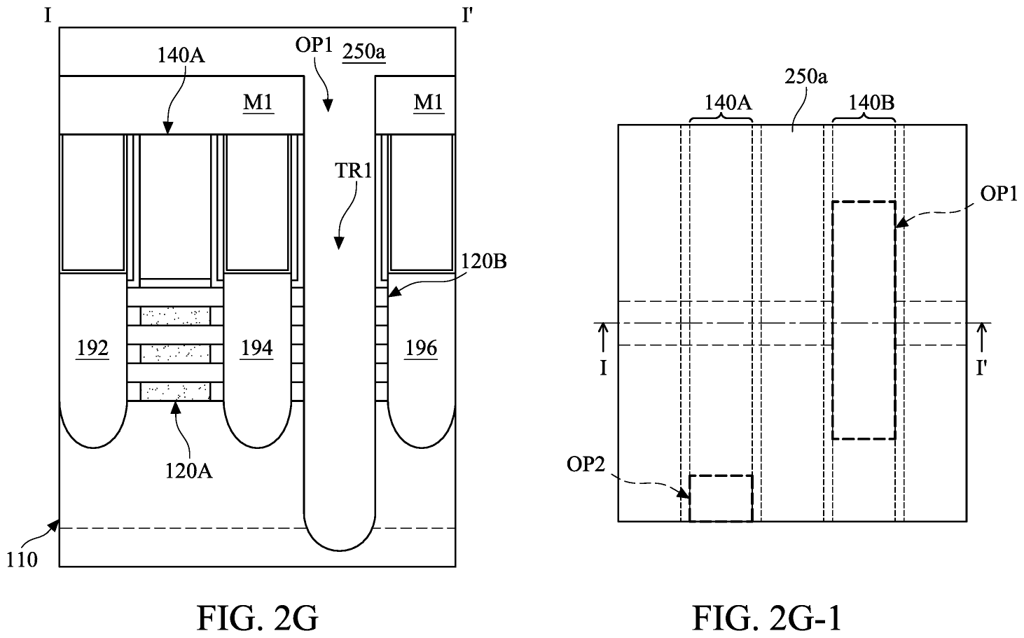

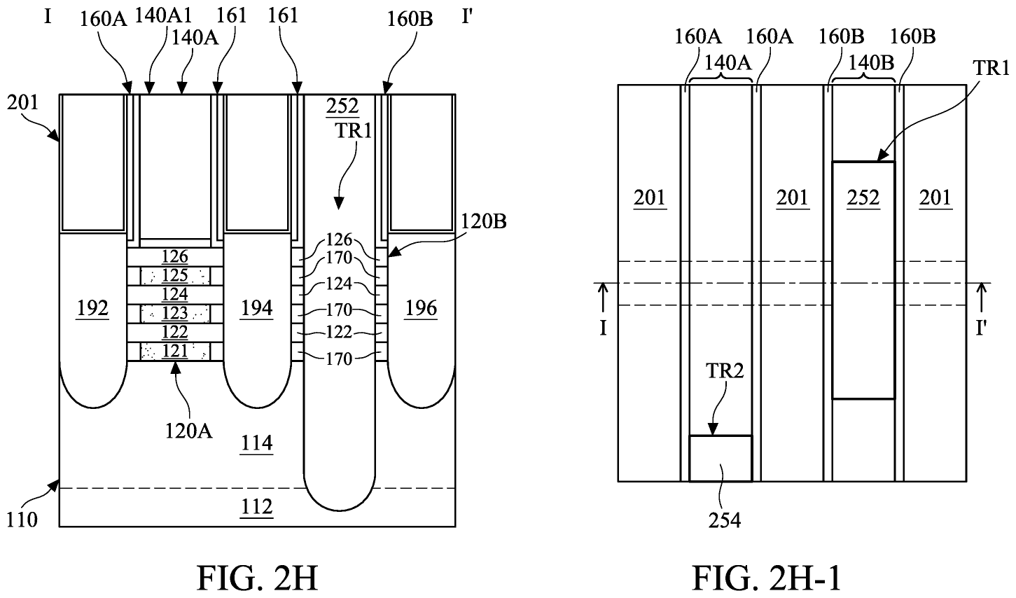

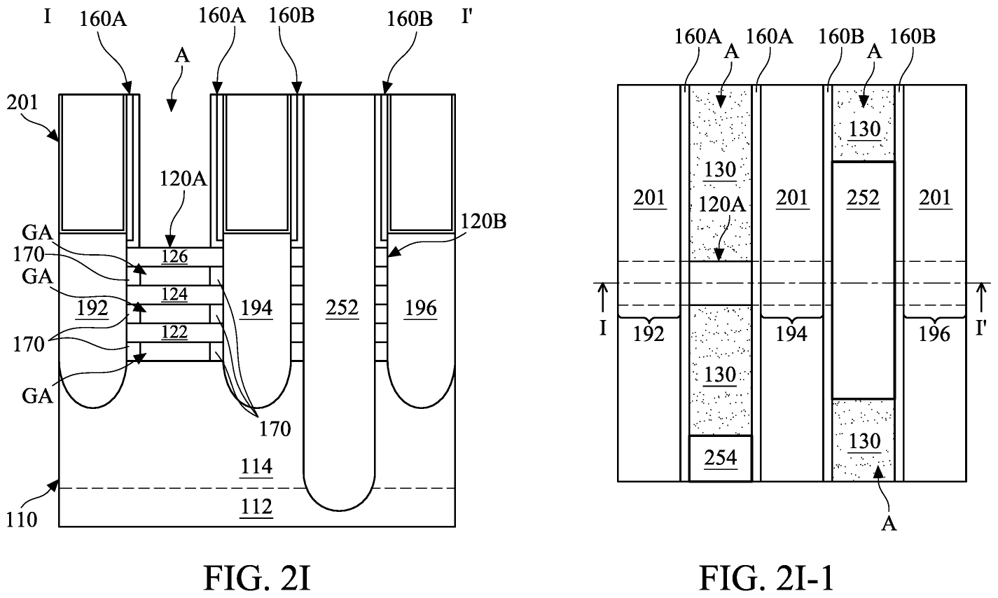

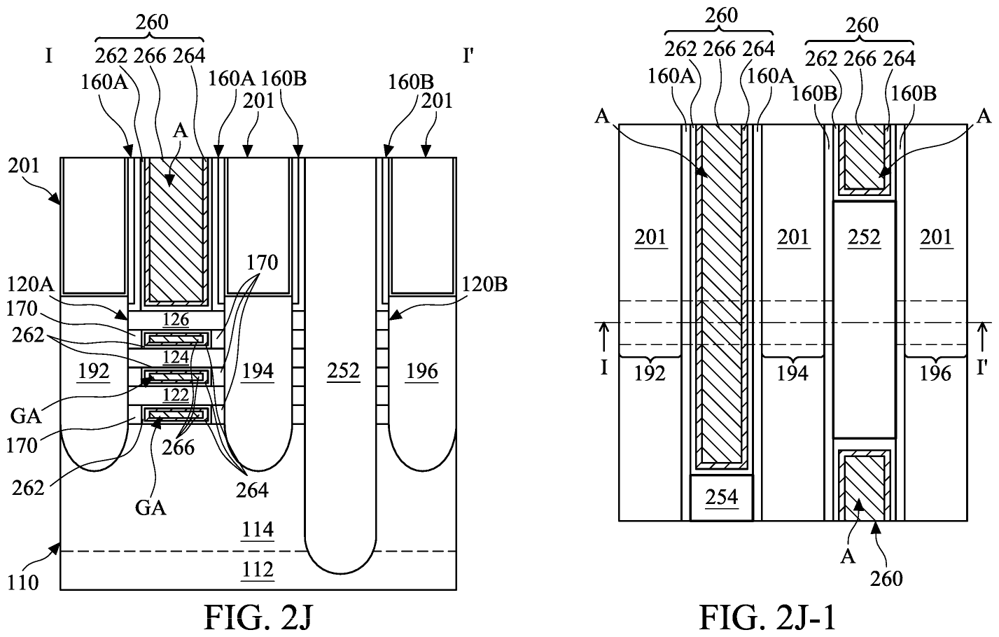

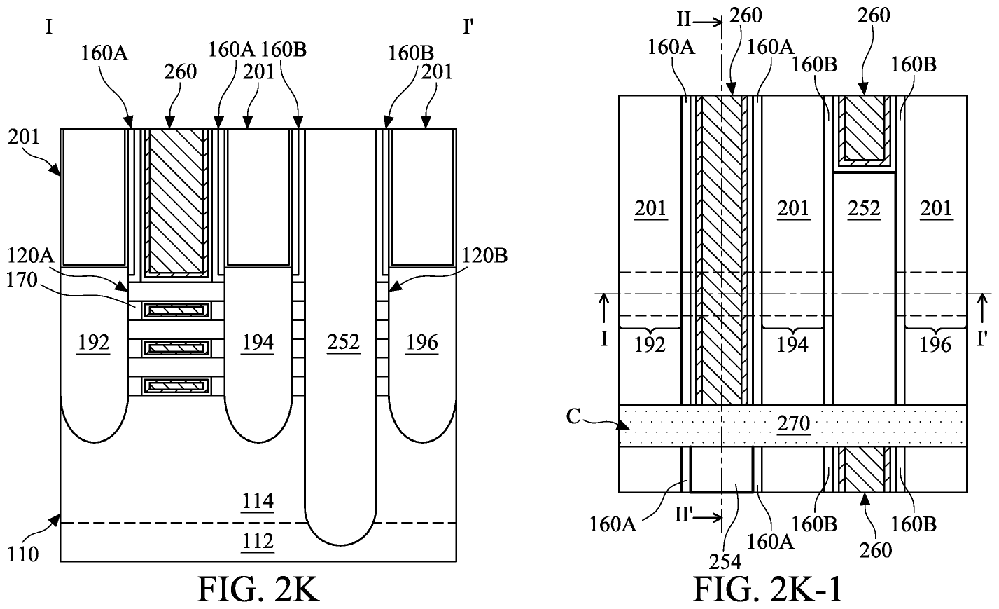

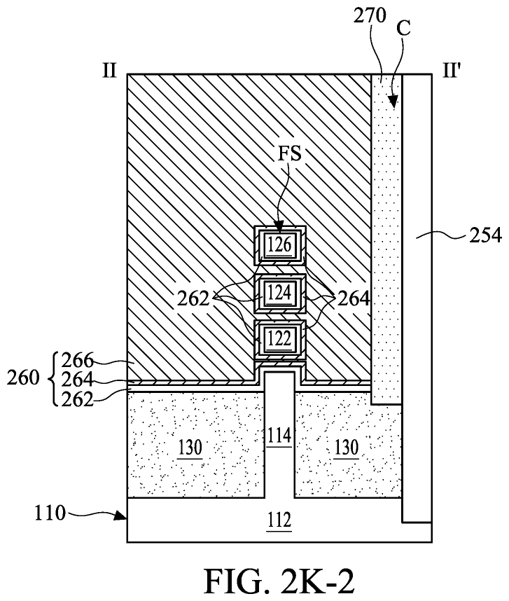

FIG. 2A is a cross-sectional view illustrating the semiconductor device structure along a sectional line I-I′ in FIG. 1B, in accordance with some embodiments. As shown in FIGS. 1B, 1B-1, and 2A, gate stacks 140A and 140B and a mask layer 150 are formed over the nanostructure stack 120, the fin 114, and the isolation layer 130, in accordance with some embodiments.

The gate stack 140A includes a gate dielectric layer 141a and a gate electrode 143a, in accordance with some embodiments. The gate electrode 143a is over the gate dielectric layer 141a, in accordance with some embodiments. The gate dielectric layer 141a is positioned between the gate electrode 143a and the nanostructure stack 120, in accordance with some embodiments.

The gate dielectric layer 141a is also positioned between the gate electrode 143a and the fin 114, in accordance with some embodiments. The gate dielectric layer 141a is positioned between the gate electrode 143a and the isolation layer 130, in accordance with some embodiments.

The gate dielectric layer 141a is made of an oxide-containing material such as silicon oxide, in accordance with some embodiments. The gate dielectric layer 141a is formed using a chemical vapor deposition process and an etching process, in accordance with some embodiments.

The gate electrode 143a is made of a semiconductor material such as polysilicon, in accordance with some embodiments. The gate electrode 143a is formed using a chemical vapor deposition process and an etching process, in accordance with some embodiments.

The gate stack 140B includes a gate dielectric layer 141b and a gate electrode 143b, in accordance with some embodiments. The gate electrode 143b is over the gate dielectric layer 141b, in accordance with some embodiments. The gate dielectric layer 141b is positioned between the gate electrode 143b and the nanostructure stack 120, in accordance with some embodiments.

The gate dielectric layer 141b is also positioned between the gate electrode 143b and the fin 114, in accordance with some embodiments. The gate dielectric layer 141b is positioned between the gate electrode 143b and the isolation layer 130, in accordance with some embodiments.

The gate dielectric layer 141b is made of an oxide-containing material such as silicon oxide, in accordance with some embodiments. The gate dielectric layer 141b is formed using a chemical vapor deposition process and an etching process, in accordance with some embodiments.

The gate electrode 143b is made of a semiconductor material such as polysilicon, in accordance with some embodiments. The gate electrode 143b is formed using a chemical vapor deposition process and an etching process, in accordance with some embodiments.

The mask layer 150 is positioned over the gate stacks 140A and 140B, in accordance with some embodiments. The mask layer 150 is made of a different material than the gate stacks 140A and 140B, in accordance with some embodiments. The mask layer 150 is made of nitrides (e.g., silicon nitride) or oxynitride (e.g., silicon oxynitride), in accordance with some embodiments.

As shown in FIGS. 1B, 1B-1, and 2A, a gate spacer 160A is formed over sidewalls 140A1 and 152 of the gate stack 140A and the mask layer 150, in accordance with some embodiments. The gate spacer 160A surrounds the gate stack 140A and the mask layer 150, in accordance with some embodiments.

As shown in FIGS. 1B, 1B-1, and 2A, a gate spacer 160B is formed over sidewalls 140B1 and 152 of the gate stack 140B and the mask layer 150, in accordance with some embodiments. The gate spacer 160B surrounds the gate stack 140B and the mask layer 150, in accordance with some embodiments.

The gate spacers 160A and 160B are positioned over the fin structure FS and the isolation layer 130, in accordance with some embodiments. In some embodiments, each of the gate spacers 160A and 160B includes layers 162 and 164. The layer 162 conformally covers the fin structure FS and the sidewalls 140A1, 140B1, and 152 of the gate stacks 140A and 140B and the mask layer 150, in accordance with some embodiments. The layer 164 is over the layer 162, in accordance with some embodiments.

The layers 162 and 164 are made of different materials, in accordance with some embodiments. The etch resistance of the layer 164 is greater than that of the layer 162, in accordance with some embodiments. The dielectric constant of the layer 164 is greater than that of the layer 162, in accordance with some embodiments.

The gate spacers 160A and 160B are made of a dielectric material such as an oxide-containing material (e.g., silicon oxide or SiCO), an nitride-containing material (e.g., silicon nitride or SiCN), an oxynitride-containing material (e.g., silicon oxynitride or SiCON), or a high-K material (e.g., HfO₂, La₂O₃, CaO, ZrO₂, HfZrO₂, or Al₂O₃), in accordance with some embodiments. The k-value of the high-K material is greater than 7.

The gate spacers 160A and 160B are made of a material different from that of the gate stacks 140A and 140B and the mask layer 150, in accordance with some embodiments. The formation of the gate spacers 160A and 160B includes deposition processes and an anisotropic etching process, in accordance with some embodiments.

FIGS. 2A-2M are cross-sectional views of various stages of a process for forming a semiconductor device structure, in accordance with some embodiments. After the step of FIG. 2A, as shown in FIG. 2B, portions of the fin structure FS, which are not covered by the gate stacks 140A and 140B and the gate spacers 160A and 160B, are removed, in accordance with some embodiments. The removal process forms trenches TR in the fin structure FS, in accordance with some embodiments.

As shown in FIG. 2B, the nanostructure stack 120 is divided into nanostructure stacks 120A and 120B by the trenches TR, in accordance with some embodiments. The trenches TR pass through the nanostructure stack 120, in accordance with some embodiments. As shown in FIG. 2B, sidewalls of the nanostructure stack 120A are substantially aligned with (or substantially coplanar with) sidewalls of the gate spacer 160A thereover, in accordance with some embodiments.

Similarly, sidewalls of the nanostructure stack 120B are substantially aligned with (or substantially coplanar with) the sidewalls of the gate spacer 160B thereover, in accordance with some embodiments.

As shown in FIG. 2B, upper portions U1 and U2 of the fin 114 are remained under the gate stacks 140A and 140B and the gate spacers 160A and 160B after the removal process, in accordance with some embodiments. The upper portions U1 and U2 are also referred to as channel portions, in accordance with some embodiments.

The removal process includes an etching process, in accordance with some embodiments. The etching process includes an anisotropic etching process such as a dry etching process, in accordance with some embodiments.

As shown in FIG. 2C, portions of the nanostructures 121, 123, and 125 are removed through the trenches TR, in accordance with some embodiments. The removal process forms recesses R1 and R2, in accordance with some embodiments. The recesses R1 are in the nanostructure stack 120A, in accordance with some embodiments. The recesses R2 are in the nanostructure stack 120B, in accordance with some embodiments.

As shown in FIG. 2C, an inner spacer layer 170 is formed in the recesses R1 and R2 of the nanostructure stacks 120A and 120B, in accordance with some embodiments. The inner spacer layer 170 is in direct contact with the nanostructure stacks 120A and 120B, in accordance with some embodiments.

As shown in FIG. 2C, the sidewalls of the inner spacer layer 170 are substantially aligned with (or substantially coplanar with) the sidewalls of the gate spacers 160A and 160B thereover, in accordance with some embodiments.

The inner spacer layer 170 is made of an insulating material, such as an oxide-containing material (e.g., silicon oxide or SiCO), a nitride-containing material (e.g., silicon nitride or SiCN), an oxynitride-containing material (e.g., silicon oxynitride or SiCON), a carbide-containing material (e.g., silicon carbide), a high-K material (e.g., HfO₂, La₂O₃, CaO, ZrO₂, HfZrO₂, or Al₂O₃), or a low-k material, in accordance with some embodiments. The k-value of the high-K material is greater than 7. The term “low-k material” means a material having a dielectric constant less than the dielectric constant of silicon dioxide, in accordance with some embodiments.

In some embodiments, the inner spacer layer 170 is formed using a deposition process and an etching process. The deposition process includes a physical vapor deposition process, a chemical vapor deposition process, an atomic layer deposition process, or the like, in accordance with some embodiments. In some other embodiments, the inner spacer layer 170 is formed using a selective deposition process such as an atomic layer deposition process.

FIG. 2D-1 is a top view of the semiconductor device structure of FIG. 2D, in accordance with some embodiments. FIG. 2D is a cross-sectional view illustrating the semiconductor device structure along a sectional line I-I′ in FIG. 2D-1, in accordance with some embodiments.

As shown in FIGS. 2D and 2D-1, source/drain structures 192, 194, and 196 are formed in the trenches TR and over the fin 114, in accordance with some embodiments. The nanostructure stack 120A and the upper portion U1 of the fin 114 are between the source/drain structures 192 and 194, in accordance with some embodiments.

The nanostructure stack 120B and the upper portion U2 of the fin 114 are between the source/drain structures 194 and 196, in accordance with some embodiments. The source/drain structures 192 and 194 are in direct contact with the nanostructures 122, 124, and 126 of the nanostructure stack 120A, the gate spacer 160A, and the inner spacer layer 170, in accordance with some embodiments.

The source/drain structures 194 and 196 are in direct contact with the nanostructures 122, 124, and 126 of the nanostructure stack 120B, the gate spacer 160B, and the inner spacer layer 170, in accordance with some embodiments. The source/drain structures 192, 194, and 196 are also referred to as stressor structures, in accordance with some embodiments.

In some embodiments, the source/drain structures 192, 194, and 196 are made of a semiconductor material and N-type dopants. The source/drain structures 192, 194, and 196 are in-situ doped with or implanted with N-type dopants, in accordance with some embodiments. The N-type dopants include the Group VA element, in accordance with some embodiments. The Group VA element includes phosphor (P), antimony (Sb), or another suitable Group VA material.

In some embodiments, a concentration of the Group VA element ranges from about 1E20 atoms/cm³ to about 5E20 atoms/cm³. In some embodiments, the atomic percentage of the Group VA element in the source/drain structures 192, 194, and 196 ranges from about 1% to about 5%. The source/drain structures 192, 194, and 196 are also referred to as doped structures, in accordance with some embodiments.

In some embodiments, the source/drain structures 192, 194, and 196 are made of a semiconductor material (e.g., silicon germanium) with P-type dopants, such as the Group IIIA element, in accordance with some embodiments. The Group IIIA element includes boron or another suitable material. The source/drain structures 192, 194, and 196 are formed using an epitaxial process, in accordance with some embodiments.

As shown in FIGS. 2D and 2D-1, an etch stop layer 210 is formed over the source/drain structures 192, 194, and 196 and the isolation layer 130, in accordance with some embodiments. The etch stop layer 210 surrounds the gate stacks 140A and 140B, in accordance with some embodiments. The etch stop layer 210 is made of a nitride-containing material, such as silicon nitride or silicon oxynitride, in accordance with some embodiments.

As shown in FIGS. 2D and 2D-1, a dielectric layer 220 is formed over the etch stop layer 210, in accordance with some embodiments. The dielectric layer 220 surrounds the gate stacks 140A and 140B, in accordance with some embodiments. The etch stop layer 210 and the dielectric layer 220 together form a dielectric structure 201, in accordance with some embodiments. The dielectric structure 201 surrounds the gate stacks 140A and 140B, in accordance with some embodiments.

The etch stop layer 210 and the dielectric layer 220 are made of different materials, in accordance with some embodiments. The dielectric layer 220 includes a dielectric material such as an oxide-containing material (e.g., silicon oxide), an oxynitride-containing material (e.g., silicon oxynitride), a low-k material, a porous dielectric material, glass, or a combination thereof, in accordance with some embodiments.

The glass includes borosilicate glass (BSG), phosphoric silicate glass (PSG), borophosphosilicate glass (BPSG), fluorinated silicate glass (FSG), or a combination thereof, in accordance with some embodiments. The dielectric layer 220 is formed by a deposition process (e.g., a chemical vapor deposition process) and a planarization process (e.g., a chemical mechanical polishing process), in accordance with some embodiments. The planarization process may also remove the mask layer 150 and the upper portions of the gate spacers 160A and 160B.

FIG. 2E-1 is a top view of the semiconductor device structure of FIG. 2E, in accordance with some embodiments. FIG. 2E is a cross-sectional view illustrating the semiconductor device structure along a sectional line I-I′ in FIG. 2E-1, in accordance with some embodiments.

As shown in FIGS. 2E and 2E-1, a mask layer M1 is formed over the dielectric structure 201, the gate spacers 160A and 160B, and the gate stacks 140A and 140B, in accordance with some embodiments. The mask layer M1 has openings OP1 and OP2, in accordance with some embodiments.

The openings OP1 and OP2 expose portions of the gate stacks 140A and 140B, in accordance with some embodiments. The mask layer M1 is made of a polymer material (e.g., a photoresist material), nitrides (e.g., silicon nitride), or oxynitride (e.g., silicon oxynitride), in accordance with some embodiments.

FIG. 2F-1 is a top view of the semiconductor device structure of FIG. 2F, in accordance with some embodiments. FIG. 2F is a cross-sectional view illustrating the semiconductor device structure along a sectional line I-I′ in FIG. 2F-1, in accordance with some embodiments.

As shown in FIGS. 2F and 2F-1, portions of the gate stacks 140A and 140B, the nanostructure stacks 120A and 120B thereunder, and the fin 114 originally wrapped by the gate stacks 140A and 140B are removed through the openings OP1 and OP2 of the mask layer M1, in accordance with some embodiments.

The removal process forms a trench TR1 passing through the gate spacer 160B, the nanostructure stack 120B, and the fin 114 originally wrapped by the gate stack 140B, in accordance with some embodiments. The trench TR1 extends into the base 112, in accordance with some embodiments.

Similarly, the removal process forms a trench TR2 passing through the gate spacer 160A, the nanostructure stack 120A, and the fin 114 originally wrapped by the gate stack 140A, in accordance with some embodiments.

The removal process includes an etching process, in accordance with some embodiments. The etching process includes an anisotropic etching process such as a dry etching process, in accordance with some embodiments.

FIG. 2G-1 is a top view of the semiconductor device structure of FIG. 2G, in accordance with some embodiments. FIG. 2G is a cross-sectional view illustrating the semiconductor device structure along a sectional line I-I′ in FIG. 2G-1, in accordance with some embodiments.

As shown in FIGS. 2G and 2G-1, a dielectric layer 250a is deposited over the mask layer M1, the dielectric structure 201, the gate spacers 160A and 160B, the source/drain structures 192, 194 and 196, and the substrate 110, in accordance with some embodiments.

The dielectric layer 250a is made of a dielectric material such as an oxide-containing material (e.g., silicon oxide or SiCO), an nitride-containing material (e.g., silicon nitride or SiCN), an oxynitride-containing material (e.g., silicon oxynitride or SiCON), or a high-K material (e.g., HfO₂, La₂O₃, CaO, ZrO₂, HfZrO₂, or Al₂O₃), in accordance with some embodiments. The k-value of the high-K material is greater than 7. The deposition process includes a chemical vapor deposition (CVD) process or a physical vapor deposition (PVD) process, in accordance with some embodiments.

FIG. 2H-1 is a top view of the semiconductor device structure of FIG. 2H, in accordance with some embodiments. FIG. 2H is a cross-sectional view illustrating the semiconductor device structure along a sectional line I-I′ in FIG. 2H-1, in accordance with some embodiments.

As shown in FIGS. 2G, 2H, and 2H-1, the mask layer M1 and the upper portion of the dielectric layer 250a are removed, in accordance with some embodiments. A portion of the dielectric layer 250a remains in the trench TR1 and forms a dielectric isolation structure 252, in accordance with some embodiments. The trench TR1 is filled up with the dielectric isolation structure 252, in accordance with some embodiments.

The dielectric isolation structure 252 passes through the gate spacer 160B, the nanostructure stack 120B, and the fin 114, in accordance with some embodiments. The dielectric isolation structure 252 is in direct contact with the gate spacer 160B, the inner spacer layer 170, the nanostructure stack 120B, and the fin 114, in accordance with some embodiments. The dielectric isolation structure 252 is also referred to as a dielectric channel-cut structure, in accordance with some embodiments.

Similarly, a portion of the dielectric layer 250a remains in the trench TR2 and forms a dielectric isolation structure 254, in accordance with some embodiments. The trench TR2 is filled up with the dielectric isolation structure 254, in accordance with some embodiments. The dielectric isolation structure 254 is also referred to as a dielectric channel-cut structure, in accordance with some embodiments.

The removal process includes a planarization process such as a chemical mechanical polishing process, in accordance with some embodiments. The top surfaces 140A1 and 161 of the gate stack 140A and the gate spacers 160A and 160B are substantially level with each other after the removal process, in accordance with some embodiments.

FIG. 2I-1 is a top view of the semiconductor device structure of FIG. 2I, in accordance with some embodiments. FIG. 2I is a cross-sectional view illustrating the semiconductor device structure along a sectional line I-I′ in FIG. 2I-1, in accordance with some embodiments.

As shown in FIGS. 2I and 2I-1, the gate stacks 140A and 140B are removed, in accordance with some embodiments. The removal process forms trenches A in the gate spacers 160A and 160B, in accordance with some embodiments.

As shown in FIGS. 2H, 2I, and 2I-1, the nanostructures 121, 123, and 125 are removed through the trenches A to form gaps GA between the fin 114 and the nanostructures 122, 124, and 126, in accordance with some embodiments. The removal process includes an etching process such as a wet etching process or a dry etching process, in accordance with some embodiments.

FIG. 2J-1 is a top view of the semiconductor device structure of FIG. 2J, in accordance with some embodiments. FIG. 2J is a cross-sectional view illustrating the semiconductor device structure along a sectional line I-I′ in FIG. 2J-1, in accordance with some embodiments.

As shown in FIGS. 2J and 2J-1, gate stacks 260 are formed in the trenches A and the gaps GA between the fin 114 and the nanostructures 122, 124, and 126, in accordance with some embodiments. The trenches A and the gaps GA are filled up with the gate stacks 260, in accordance with some embodiments.

The gate stack 260 is wrapped around the fin 114 and the nanostructures 122, 124, and 126, in accordance with some embodiments. As shown in FIG. 2J, the source/drain structure 194 is between the nanostructures 122, 124 and 126 and the dielectric isolation structure 252, in accordance with some embodiments. The dielectric structure 201 separates the gate stack 260 from the dielectric isolation structure 252, in accordance with some embodiments.

Each gate stack 260 includes a gate dielectric layer 262, a work function metal layer 264, and a gate electrode layer 266, in accordance with some embodiments. The gate dielectric layer 262 is formed over the nanostructures 122, 124, and 126, the fin 114, the gate spacers 160A and 160B, and the inner spacer layer 170, in accordance with some embodiments.

The gate dielectric layer 262 conformally covers the nanostructures 122, 124, and 126, the fin 114, the gate spacers 160A and 160B, and the inner spacer layer 170, in accordance with some embodiments. The gate dielectric layer 262 surrounds the nanostructures 122, 124, and 126, in accordance with some embodiments.

The gate dielectric layer 262 is made of a high-K material, such as HfO₂, La₂O₃, CaO, ZrO₂, HfZrO₂, or Al₂O₃, in accordance with some embodiments. The gate dielectric layer 262 is formed using an atomic layer deposition process or another suitable deposition process and a planarization process such as a chemical mechanical polishing process.

The work function metal layer 264 is conformally formed over the gate dielectric layer 262, in accordance with some embodiments. The work function metal layer 264 provides a desired work function for transistors to enhance device performance including improved threshold voltage.

In the embodiments of forming an NMOS transistor, the work function metal layer 264 can be a metal capable of providing a work function value suitable for the device, such as equal to or less than about 4.5 eV.

The work function metal layer 264 is made of metal, metal carbide, metal nitride, or a combination thereof, in accordance with some embodiments. For example, the work function metal layer 264 is made of tantalum, hafnium carbide, zirconium carbide, tantalum nitride, or a combination thereof.

In the embodiments of forming a PMOS transistor, the work function metal layer 264 can be a metal capable of providing a work function value suitable for the device, such as equal to or greater than about 4.8 eV.

The work function metal layer 264 is made of metal, metal carbide, metal nitride, another suitable material, or a combination thereof, in accordance with some embodiments. For example, the work function metal layer 264 is made of titanium, titanium nitride, another suitable material, or a combination thereof.

The work function metal layer 264 is formed using a deposition process, in accordance with some embodiments. The deposition process includes a physical vapor deposition process, a chemical vapor deposition process, an atomic layer deposition process, or a combination thereof, in accordance with some embodiments.

The gate electrode layer 266 is formed over the work function metal layer 264, in accordance with some embodiments. The gate electrode layer 266 is made of metal, metal nitride, or metal carbide, in accordance with some embodiments. The gate electrode layer 266 is made of tungsten, titanium nitride, tantalum nitride, titanium aluminide, titanium carbide, or a combination thereof, in accordance with some embodiments.

The gate electrode layer 266 is formed using an atomic layer deposition process, a chemical vapor deposition process, or a physical vapor deposition process, in accordance with some embodiments.

FIG. 2K-1 is a top view of the semiconductor device structure of FIG. 2K, in accordance with some embodiments. FIG. 2K is a cross-sectional view illustrating the semiconductor device structure along a sectional line I-I′ in FIG. 2K-1, in accordance with some embodiments. FIG. 2K-2 is a cross-sectional view illustrating the semiconductor device structure along a sectional line II-II′ in FIG. 2K-1, in accordance with some embodiments.

As shown in FIGS. 2K, 2K-1, and 2K-2, portions of the gate stacks 260, the dielectric structure 201, and the isolation layer 130 are removed to form a trench C passing through the gate stacks 260, in accordance with some embodiments.

The removal process includes an etching process, in accordance with some embodiments. The etching process includes an anisotropic etching process such as a dry etching process, in accordance with some embodiments.

As shown in FIGS. 2K, 2K-1, and 2K-2, a gate-cut structure 270 is formed in the trench C, in accordance with some embodiments. The trench C is filled up with the gate-cut structure 270, in accordance with some embodiments. The gate-cut structure 270 is also referred to as a metal gate-cut structure, in accordance with some embodiments.

The gate-cut structure 270 are made of a nitride-containing material (e.g., silicon nitride), an oxynitride-containing material (e.g., silicon oxynitride), or the like, in accordance with some embodiments. The gate-cut structure 270 are formed by a deposition process (e.g., a chemical vapor deposition process) and a planarization process (e.g., a chemical mechanical polishing process), in accordance with some embodiments.

FIG. 2L-1 is a top view of the semiconductor device structure of FIG. 2L, in accordance with some embodiments. FIG. 2L is a cross-sectional view illustrating the semiconductor device structure along a sectional line I-I′ in FIG. 2L-1, in accordance with some embodiments.

As shown in FIGS. 2L and 2L-1, portions of the dielectric structure 201 are removed to form through holes TH1, TH2, and TH3 passing through the dielectric structure 201, in accordance with some embodiments. The through holes TH1, TH2, and TH3 extend into the source/drain structures 192, 194, and 196 respectively, in accordance with some embodiments.

As shown in FIGS. 2L and 2L-1, metal silicide layers 282, 284, and 286 are respectively formed over the source/drain structures 192, 194, and 196 exposed by the through holes TH1, TH2, and TH3, in accordance with some embodiments. The metal silicide layer 284 or 286 is wider than the metal silicide layer 282, in accordance with some embodiments.

Therefore, the contact area between the metal silicide layer 284 (or 286) and the source/drain structure 194 (or 196) is greater than that between the metal silicide layer 282 and the source/drain structure 192, in accordance with some embodiments. As a result, the (wider) metal silicide layer 284 (or 286) can effectively decrease the contact resistance between the metal silicide layer 284 (or 286) and the source/drain structure 194 (or 196), in accordance with some embodiments. The metal silicide layers 282, 284, and 286 are made of TiSi₂ (titanium disilicide), CoSi₂, or RuSi, in accordance with some embodiments.

As shown in FIGS. 2L and 2L-1, contact structures 292, 294, and 296 are respectively formed in the through holes TH1, TH2, and TH3, in accordance with some embodiments. The contact structures 292, 294, and 296 are respectively formed over the metal silicide layers 282, 284, and 286, in accordance with some embodiments.

In some embodiments, an average width of the contact structure 294 (or 296) is greater than an average width of the contact structure 292. The ratio of the average width of the contact structure 294 (or 296) to that of the contact structure 292 ranges from about 1.1 to about 4, in accordance with some embodiments.

The inner spacer layer 170 can electrically insulate the nanostructure stack 120B from the fin 114 even if the contact structure (e.g. 294 or 296) shorts the nanostructure stack 120B, in accordance with some embodiments. Therefore, the contact structure (e.g. 294 or 296) adjacent to the dielectric isolation structure 252 can extend toward the dielectric isolation structure 252 to have a greater width, which decrease the contact resistance between the contact structure (e.g. 294 or 296) and the source/drain structure (e.g., 194 or 196) thereunder, in accordance with some embodiments.

The dielectric isolation structure 252 is closer to the contact structure 294 than the gate stack 260, in accordance with some embodiments. The ratio of the average distance between the contact structure 294 and the dielectric isolation structure 252 to the average distance between the contact structure 294 and the gate stack 260 is less than about 0.9, in accordance with some embodiments.

The contact structure 294 extends into the gate spacer 160B, in accordance with some embodiments. The gate spacer 160B separates the contact structure 294 from the dielectric isolation structure 252, in accordance with some embodiments.

The contact structure 296 extends into the gate spacer 160B, in accordance with some embodiments. The gate spacer 160B separates the contact structure 296 from the dielectric isolation structure 252, in accordance with some embodiments. In some embodiments, a distance D1 between the contact structure 294 and the gate stack 260 is substantially equal to a distance D2 between the contact structure 292 and the gate stack 260.

As shown in FIG. 2L-1, the contact structure 296 has a stepped edge 296e, in accordance with some embodiments. The contact structure 296 has an L-like shape, in accordance with some embodiments. The contact structure 296 has a wide strip portion 296w and a narrow strip portion 296n, in accordance with some embodiments.

The wide strip portion 296w is closer to the dielectric isolation structure 252 than the narrow strip portion 296n, in accordance with some embodiments. The wide strip portion 296w is wider than the narrow strip portion 296n, in accordance with some embodiments.

A ratio of the width W1 of the wide strip portion 296w to the width W2 of the narrow strip portion 296n ranges from about 1.1 to about 4, in accordance with some embodiments. A distance D between the sidewall 296w1 of the wide strip portion 296w and the sidewall 296n1 of the narrow strip portion 296n ranges from about 0.5 nm to about 20 nm, in accordance with some embodiments.

As shown in FIG. 2L, an end portion 294e of the contact structure 294 is bonded to the source/drain structure 194, in accordance with some embodiments. An end portion 292e of the contact structure 292 is bonded to the source/drain structure 192, in accordance with some embodiments. An end portion 296e of the contact structure 296 is bonded to the source/drain structure 196, in accordance with some embodiments. The end portion 294e or 296e is wider than the end portion 292e, in accordance with some embodiments.

The contact structures 292, 294, and 296 are made of a conductive material, such as metal (e.g., copper, aluminum, gold, silver, or tungsten) or alloys thereof, in accordance with some embodiments. The contact structures 292, 294, and 296 are formed using a deposition process (e.g., a physical vapor deposition process) and a planarization process (e.g., a chemical mechanical polishing process), in accordance with some embodiments.

FIG. 2M-1 is a top view of the semiconductor device structure of FIG. 2M, in accordance with some embodiments. FIG. 2M is a cross-sectional view illustrating the semiconductor device structure along a sectional line I-I′ in FIG. 2M-1, in accordance with some embodiments. FIG. 2M-2 is a top view of the semiconductor device structure of FIG. 2M, in accordance with some embodiments. FIG. 2M-1 is an enlarged view of a region R of the semiconductor device structure of FIG. 2M-2, in accordance with some embodiments.

As shown in FIGS. 2M, 2M-1, and 2M-2, an etch stop layer 310 is formed over the dielectric structure 201, the contact structures 292, 294, and 296, the gate stack 260, the gate spacers 160A and 160B, and the dielectric isolation structure 252, in accordance with some embodiments.

The etch stop layer 310 is made of an insulating material, such as a nitrogen-containing material (e.g., silicon nitride), in accordance with some embodiments. The etch stop layer 310 is formed using a deposition process, such as a chemical vapor deposition (CVD) process, an atomic layer deposition (ALD) process, or a physical vapor deposition (PVD) process, in accordance with some embodiments.

As shown in FIGS. 2M, 2M-1, and 2M-2, a dielectric layer 320 is formed over the etch stop layer 310, in accordance with some embodiments. The dielectric layer 320 is made of a dielectric material such as an oxide-containing material (e.g., silicon oxide), an oxynitride-containing material (e.g., silicon oxynitride), a low-k (low dielectric constant) material, a porous dielectric material, glass, or a combination thereof, in accordance with some embodiments. The glass includes borosilicate glass (BSG), phosphoric silicate glass (PSG), borophosphosilicate glass (BPSG), fluorinated silicate glass (FSG), or a combination thereof, in accordance with some embodiments.

The dielectric layer 320 is formed using a deposition process (or a spin-on process), in accordance with some embodiments. The deposition process includes a chemical vapor deposition (CVD) process, a high density plasma chemical vapor deposition (HDPCVD) process, a flowable chemical vapor deposition (FCVD) process, a sputtering process, or a combination thereof, in accordance with some embodiments.

For the sake of simplicity, FIG. 2M-2 omits the isolation layer 130, the gate spacers 160A and 160B, the source/drain structures 192, 194, and 196, the dielectric structure 201, the etch stop layer 310, and the dielectric layer 320.

As shown in FIGS. 2M, 2M-1, and 2M-2, conductive via structures 332, 334, and 326 are formed in the etch stop layer 310 and the dielectric layer 320 and connected to the contact structures 292, 294, and 296 respectively, in accordance with some embodiments.

In this step, a semiconductor device structure 200 is substantially formed, in accordance with some embodiments. The top surfaces 261, 292a, 294a, and 296a of the gate stack 260 and the contact structures 292, 294, and 296 are substantially level with each other, in accordance with some embodiments.

The dielectric isolation structure 252 is closer to the conductive via structure 334 than the gate stack 260, in accordance with some embodiments. As shown in FIG. 2M-1, the ratio of the distance D3 between the conductive via structure 334 and the dielectric isolation structure 252 to the distance D4 between the conductive via structure 334 and the gate stack 260 is less than about 0.9, in accordance with some embodiments.

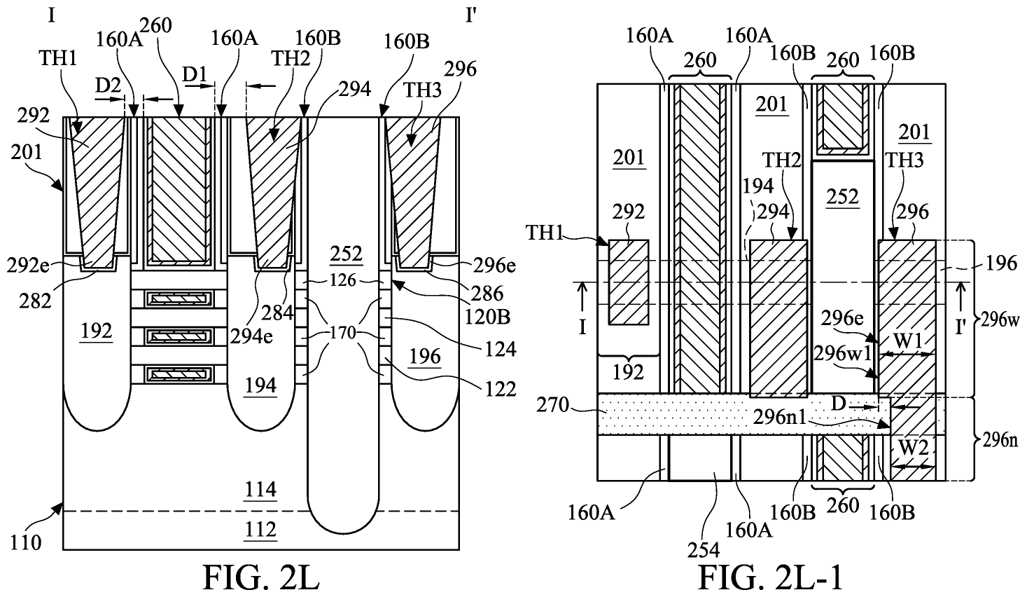

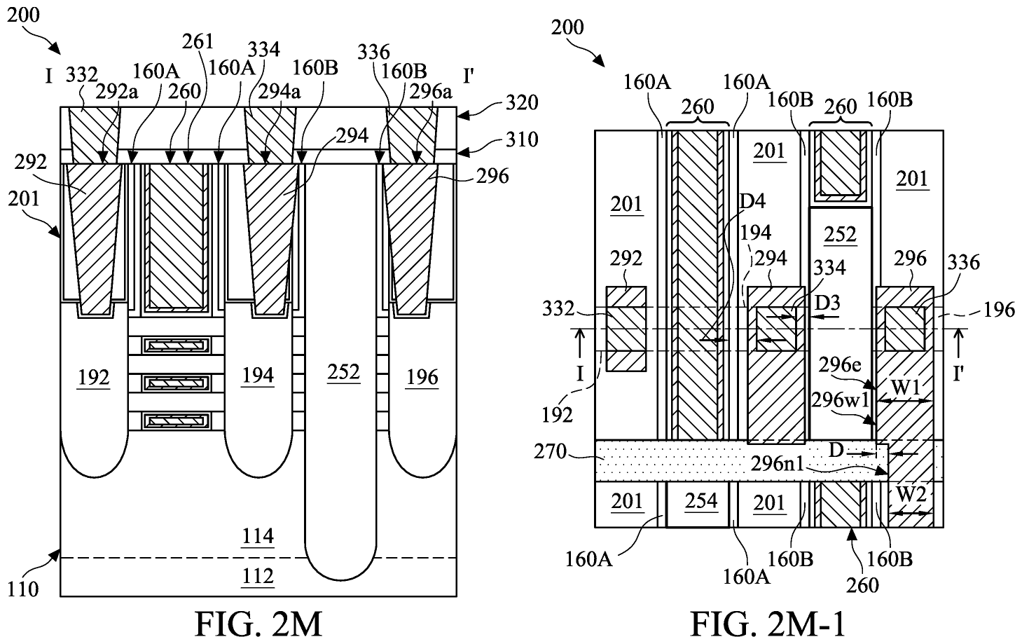

FIG. 3A is a cross-sectional view of a semiconductor device structure 300, in accordance with some embodiments. FIG. 3B is a top view of the semiconductor device structure 300 of FIG. 3A, in accordance with some embodiments. FIG. 3A is a cross-sectional view illustrating the semiconductor device structure 300 along a sectional line I-I′ in FIG. 3B, in accordance with some embodiments. For the sake of simplicity, FIGS. 3B, 4B, and 5B omit the etch stop layer 310 and the dielectric layer 320.

As shown in FIGS. 3A and 3B, the semiconductor device structure 300 is similar to the semiconductor device structure 200 of FIGS. 2M and 2M-1, except that the contact structures 294 and 296 pass through the gate spacer 160B and extend into the dielectric isolation structure 252, in accordance with some embodiments.

As shown in FIG. 3B, the wide strip portion 296w of the contact structure 296 extends into the gate spacer 160B, in accordance with some embodiments. The wide strip portion 296w penetrates through the gate spacer 160B, in accordance with some embodiments. The wide strip portion 296w extends into the dielectric isolation structure 252, in accordance with some embodiments.

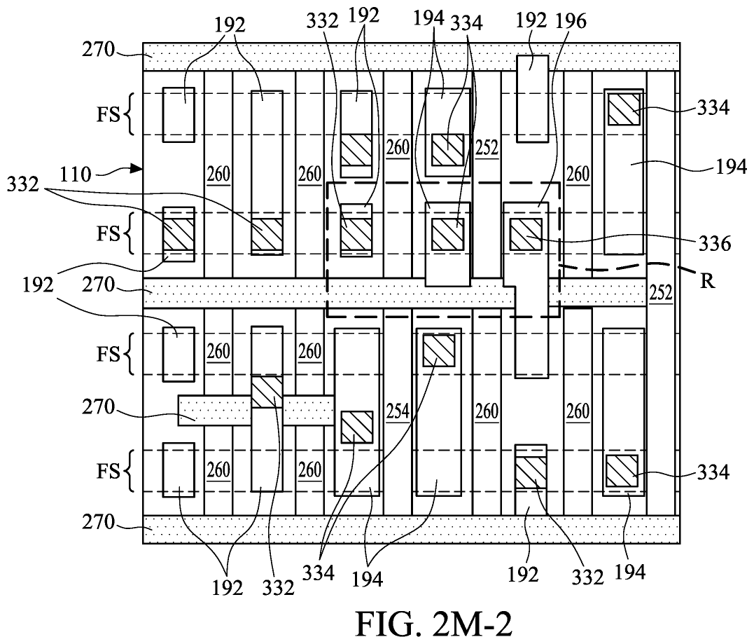

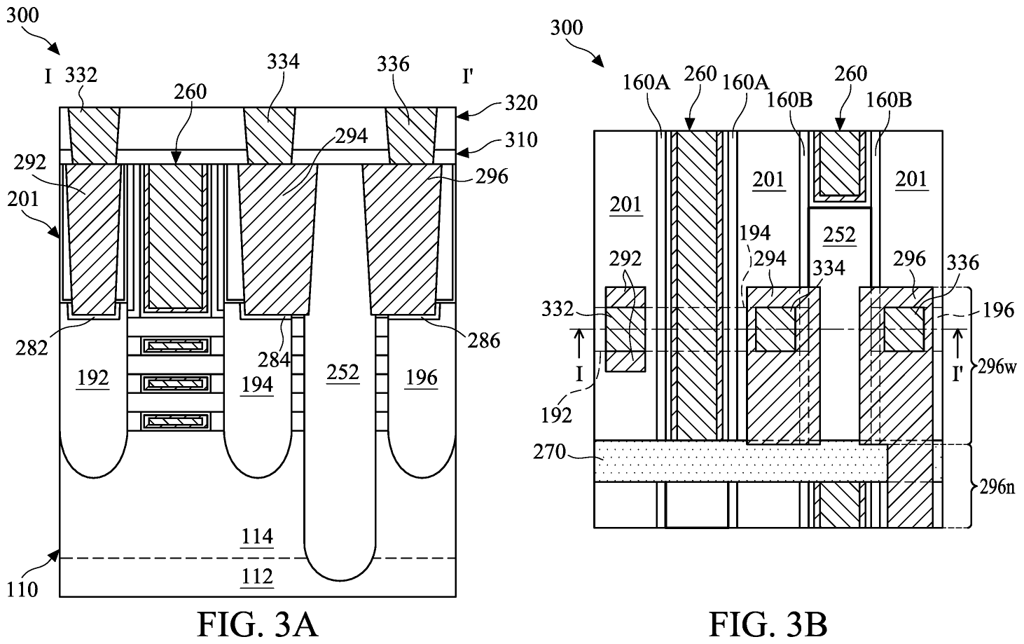

FIG. 4A is a cross-sectional view of a semiconductor device structure 400, in accordance with some embodiments. FIG. 4B is a top view of the semiconductor device structure 400 of FIG. 4A, in accordance with some embodiments. FIG. 4A is a cross-sectional view illustrating the semiconductor device structure 400 along a sectional line I-I′ in FIG. 4B, in accordance with some embodiments.

As shown in FIGS. 4A and 4B, the semiconductor device structure 400 is similar to the semiconductor device structure 300 of FIGS. 3A and 3B, except that the conductive via structure 334 or 336 is wider than the conductive via structure 332, in accordance with some embodiments. The width of the conductive via structure 334 is equal to or less than that of the contact structure 294, in accordance with some embodiments.

The width of the conductive via structure 336 is equal to or less than that of the contact structure 296, in accordance with some embodiments. A ratio of the width of the conductive via structure 334 or 336 to the width of the conductive via structure 332 ranges from about 1.1 to about 4, in accordance with some embodiments.

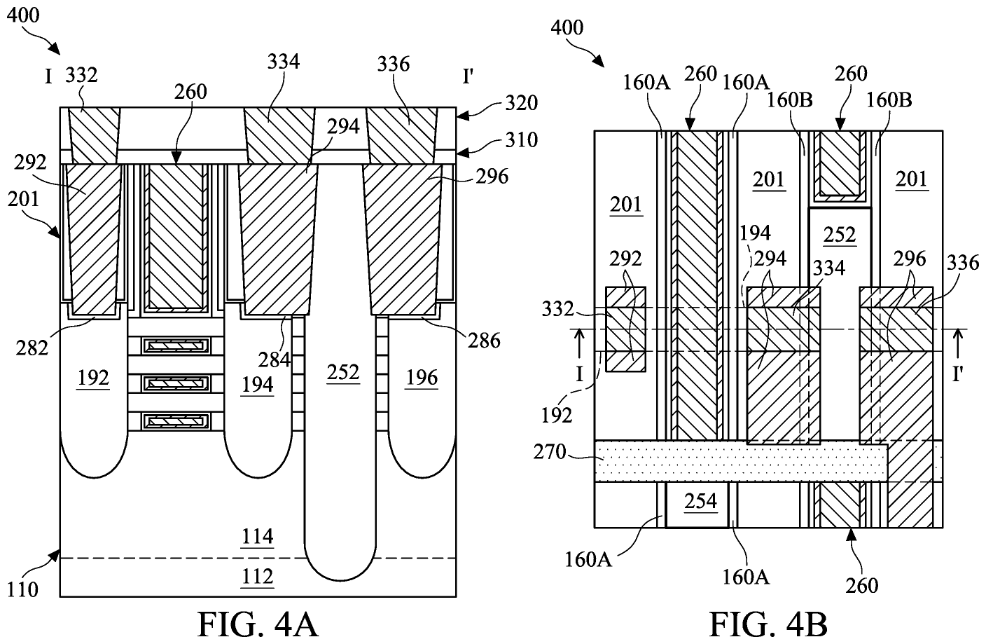

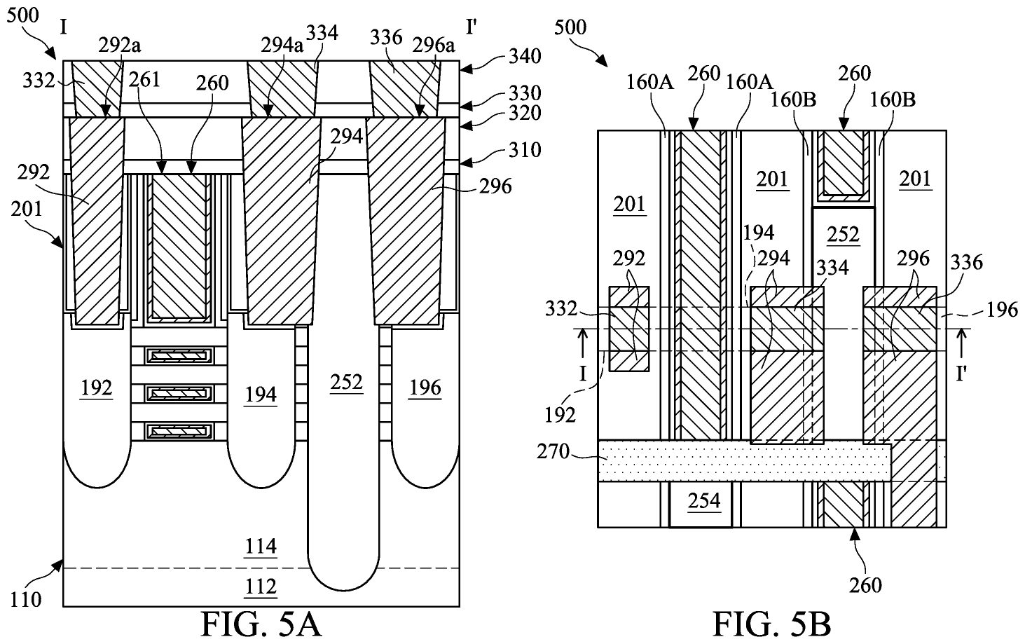

FIG. 5A is a cross-sectional view of a semiconductor device structure 500, in accordance with some embodiments. FIG. 5B is a top view of the semiconductor device structure 500 of FIG. 5A, in accordance with some embodiments. FIG. 5A is a cross-sectional view illustrating the semiconductor device structure 500 along a sectional line I-I′ in FIG. 5B, in accordance with some embodiments.

As shown in FIGS. 5A and 5B, the semiconductor device structure 500 is similar to the semiconductor device structure 400 of FIGS. 4A and 4B, except that the top surfaces 292a, 294a, and 296a of the contact structures 292, 294, and 296 are higher than the top surface 261 of the gate stack 260, in accordance with some embodiments.

As shown in FIGS. 5A and 5B, the contact structures 292, 294, and 296 pass through the etch stop layer 310 and the dielectric layer 320, in accordance with some embodiments. As shown in FIGS. 5A and 5B, an etch stop layer 330 is formed over the dielectric layer 320, in accordance with some embodiments.

The etch stop layer 330 is made of an insulating material, such as a nitrogen-containing material (e.g., silicon nitride), in accordance with some embodiments. The etch stop layer 330 is formed using a deposition process, such as a chemical vapor deposition (CVD) process, an atomic layer deposition (ALD) process, or a physical vapor deposition (PVD) process, in accordance with some embodiments.

As shown in FIGS. 5A and 5B, a dielectric layer 340 is formed over the etch stop layer 330, in accordance with some embodiments. The dielectric layer 340 is made of a dielectric material such as an oxide-containing material (e.g., silicon oxide), an oxynitride-containing material (e.g., silicon oxynitride), a low-k (low dielectric constant) material, a porous dielectric material, glass, or a combination thereof, in accordance with some embodiments. The glass includes borosilicate glass (BSG), phosphoric silicate glass (PSG), borophosphosilicate glass (BPSG), fluorinated silicate glass (FSG), or a combination thereof, in accordance with some embodiments.

The dielectric layer 340 is formed using a deposition process (or a spin-on process), in accordance with some embodiments. The deposition process includes a chemical vapor deposition (CVD) process, a high density plasma chemical vapor deposition (HDPCVD) process, a flowable chemical vapor deposition (FCVD) process, a sputtering process, or a combination thereof, in accordance with some embodiments.

As shown in FIGS. 5A and 5B, conductive via structures 332, 334, and 326 are formed in the etch stop layer 330 and the dielectric layer 340 and connected to the contact structures 292, 294, and 296 respectively, in accordance with some embodiments. In this step, a semiconductor device structure 500 is substantially formed, in accordance with some embodiments.

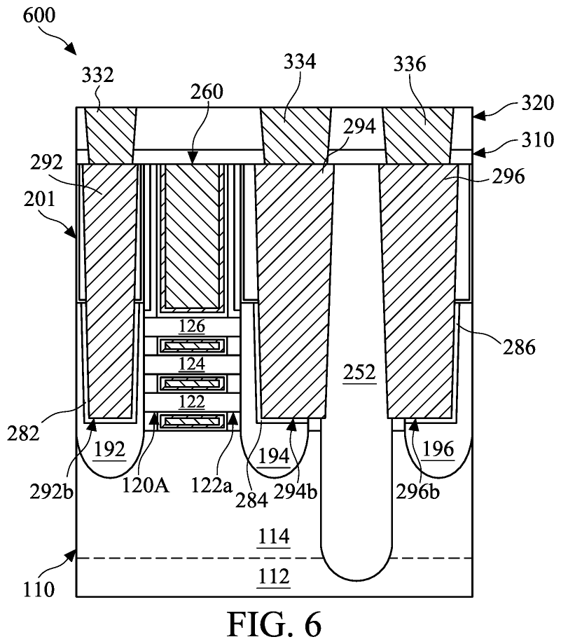

FIG. 6 is a cross-sectional view of a semiconductor device structure 600, in accordance with some embodiments. As shown in FIG. 6, the semiconductor device structure 600 is similar to the semiconductor device structure 400 of FIGS. 4A and 4B, except that the bottom surfaces 292b, 294b, and 296b of the contact structures 292, 294, and 296 are lower than the bottom surface 122a of the nanostructure 122, in accordance with some embodiments.

The contact area between the metal silicide layer 282, 284 or 286, the contact structure 292, 294, or 296, and the source/drain structure 192, 194 or 196 is increased, which decreases the contact resistance, in accordance with some embodiments. Therefore, the performance of the semiconductor device structure 600 is improved, in accordance with some embodiments.

Processes and materials for forming the semiconductor device structures 300, 400, 500 and 600 may be similar to, or the same as, those for forming the semiconductor device structure 200 described above. Elements designated by the same or similar reference numbers as those in FIGS. 1A to 6 have the same or similar structures and the materials. Therefore, the detailed descriptions thereof will not be repeated herein.

In accordance with some embodiments, semiconductor device structures and methods for forming the same are provided. The methods (for forming the semiconductor device structure) form a contact structure extending toward a dielectric isolation structure to increase the contact area between the contact structure and a source/drain structure so as to decrease the contact resistance between the contact structure and the source/drain structure. Therefore, the performance of the semiconductor device structures is improved. The methods have great process compatibility and no additional cost.

In accordance with some embodiments, a method for forming a semiconductor device structure is provided. The method includes providing a substrate and a nanostructure stack. The substrate has a base and a fin over the base, the nanostructure stack is over the fin and has a first nanostructure and a second nanostructure over the first nanostructure. The method includes forming a first gate stack and a second gate stack wrapped around the nanostructure stack. The method includes forming a first source/drain structure in the nanostructure stack and between the first gate stack and the second gate stack. The method includes removing the second gate stack, the nanostructure stack and the fin under the second gate stack to form a trench passing through the nanostructure stack and the fin. The method includes forming a dielectric isolation structure in the trench. The method includes removing the first gate stack and the first nanostructure. The method includes forming a third gate stack wrapped around the second nanostructure. The method includes forming a first contact structure over the first source/drain structure. The dielectric isolation structure is closer to the first contact structure than the first gate stack.

In accordance with some embodiments, a method for forming a semiconductor device structure is provided. The method includes providing a substrate and a nanostructure stack. The substrate has a base and a fin over the base, and the nanostructure stack is over the fin. The method includes forming a gate stack wrapped around the nanostructure stack. The method includes forming a source/drain structure in the nanostructure stack and adjacent to the gate stack. The method includes removing the gate stack, the nanostructure stack and the fin under the gate stack to form a trench passing through the nanostructure stack and the fin. The method includes forming a dielectric isolation structure in the trench. The method includes forming a contact structure over the source/drain structure. The contact structure has a wide strip portion and a narrow strip portion, and the wide strip portion is closer to the dielectric isolation structure than the narrow strip portion in a top view of the contact structure and the dielectric isolation structure.

In accordance with some embodiments, a semiconductor device structure is provided. The semiconductor device structure includes a substrate having a base and a fin over the base. The semiconductor device structure includes a nanostructure over the fin. The semiconductor device structure includes a first source/drain structure passing through the nanostructure. The semiconductor device structure includes a dielectric structure over the first source/drain structure and the base. The semiconductor device structure includes a dielectric isolation structure passing through the dielectric structure, the nanostructure, and the fin. The semiconductor device structure includes a gate stack wrapped around the nanostructure. The first source/drain structure is between the dielectric isolation structure and the gate stack. The semiconductor device structure includes a first contact structure over the first source/drain structure. The dielectric isolation structure is closer to the first contact structure than the gate stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
providing a substrate and a nanostructure stack, wherein the substrate has a base and a fin over the base, the nanostructure stack is over the fin and has a first nanostructure and a second nanostructure over the first nanostructure;
forming a first gate stack and a second gate stack wrapped around the nanostructure stack;
forming a first source/drain structure in the nanostructure stack and between the first gate stack and the second gate stack;
removing the second gate stack, the nanostructure stack and the fin under the second gate stack to form a trench passing through the nanostructure stack and the fin;
forming a dielectric isolation structure in the trench;
removing the first gate stack and the first nanostructure;
forming a third gate stack wrapped around the second nanostructure; and
forming a first contact structure over the first source/drain structure, wherein the dielectric isolation structure is closer to the first contact structure than the third gate stack.

2. The method for forming the semiconductor device structure as claimed in claim 1, further comprising:
forming a second source/drain structure in the nanostructure stack, wherein the first gate stack is between the first source/drain structure and the second source/drain structure; and
forming a second contact structure over the second source/drain structure, wherein a first average width of the first contact structure is greater than a second average width of the second contact structure.

3. The method for forming the semiconductor device structure as claimed in claim 2, further comprising:
forming a first metal silicide layer over the first source/drain structure and a second metal silicide layer over the second source/drain structure, wherein the first contact structure is formed over the first metal silicide layer, the second contact structure is formed over the second metal silicide layer, and the first metal silicide layer is wider than the second metal silicide layer.

4. The method for forming the semiconductor device structure as claimed in claim 3, wherein a first distance between the first contact structure and the third gate stack is substantially equal to a second distance between the second contact structure and the third gate stack.

5. The method for forming the semiconductor device structure as claimed in claim 2, further comprising:
forming a first conductive via structure over the first contact structure and a second conductive via structure over the second contact structure, wherein the first conductive via structure is wider than the second conductive via structure.

6. The method for forming the semiconductor device structure as claimed in claim 5, wherein the dielectric isolation structure is closer to the first conductive via structure than the third gate stack.

7. The method for forming the semiconductor device structure as claimed in claim 1, wherein the first contact structure has an L-like shape in a top view of the first contact structure.

8. The method for forming the semiconductor device structure as claimed in claim 1, further comprising:
forming a gate spacer over a sidewall of the second gate stack before the first source/drain structure is formed, wherein the trench further passes through the gate spacer, the dielectric isolation structure is adjacent to the gate spacer, and the first contact structure extends into the gate spacer.

9. The method for forming the semiconductor device structure as claimed in claim 8, wherein the first contact structure passes through the gate spacer.

10. The method for forming the semiconductor device structure as claimed in claim 8, wherein the gate spacer separates the first contact structure from the dielectric isolation structure.

11. A method for forming a semiconductor device structure, comprising:
providing a substrate and a nanostructure stack, wherein the substrate has a base and a fin over the base, and the nanostructure stack is over the fin;
forming a gate stack wrapped around the nanostructure stack;
forming a source/drain structure in the nanostructure stack and adjacent to the gate stack;
removing the gate stack, the nanostructure stack and the fin under the gate stack to form a trench passing through the nanostructure stack and the fin;
forming a dielectric isolation structure in the trench; and
forming a contact structure over the source/drain structure, wherein the contact structure has a wide strip portion and a narrow strip portion, and the wide strip portion is closer to the dielectric isolation structure than the narrow strip portion in a top view of the contact structure and the dielectric isolation structure.

12. The method for forming the semiconductor device structure as claimed in claim 11, wherein the wide strip portion of the contact structure extends into the dielectric isolation structure.

13. The method for forming the semiconductor device structure as claimed in claim 11, further comprising:
forming a gate spacer over a sidewall of the gate stack before the source/drain structure is formed, wherein the trench further passes through the gate spacer, the dielectric isolation structure is adjacent to the gate spacer, and the wide strip portion of the contact structure extends into the gate spacer.

14. The method for forming the semiconductor device structure as claimed in claim 13, wherein the wide strip portion of the contact structure penetrates through the gate spacer.

15. The method for forming the semiconductor device structure as claimed in claim 11, wherein the contact structure has a stepped edge in the top view of the contact structure and the dielectric isolation structure.

16. A semiconductor device structure, comprising:
a substrate having a base and a fin over the base;
a nanostructure over the fin;
a first source/drain structure passing through the nanostructure;
a dielectric structure over the first source/drain structure and the base;
a dielectric isolation structure passing through the dielectric structure, the nanostructure, and the fin;
a gate stack wrapped around the nanostructure, wherein the first source/drain structure is between the dielectric isolation structure and the gate stack; and
a first contact structure over the first source/drain structure, wherein the dielectric isolation structure is closer to the first contact structure than the gate stack.

17. The semiconductor device structure as claimed in claim 16, further comprising:
a second source/drain structure passing through the nanostructure, wherein the gate stack is between the first source/drain structure and the second source/drain structure; and
a second contact structure over the second source/drain structure, wherein a first average width of the first contact structure is greater than a second average width of the second contact structure.

18. The semiconductor device structure as claimed in claim 17, further comprising:
a first conductive via structure over the first contact structure; and
a second conductive via structure over the second contact structure, wherein the first conductive via structure is wider than the second conductive via structure.

19. The semiconductor device structure as claimed in claim 18, wherein the dielectric isolation structure is closer to the first conductive via structure than the gate stack.

20. The semiconductor device structure as claimed in claim 17, wherein a first end portion of the first contact structure is bonded to the first source/drain structure, a second end portion of the second contact structure is bonded to the second source/drain structure, and the first end portion is wider than the second end portion.
